(19) United States
(12) Patent Application Publication
(10) Pub. No.: US 2008/0090392 A1
(43) Pub. Date: Apr. 17, 2008

(54) Technique for Improved Damage Control in a Plasma Doping (PLAD) Ion Implantation

(75) Inventors: Vikram Singh, North Andover, MA (US); Edwin A. Arevalo, Haverhill, MA (US); Anthony Renau, West Newbury, MA (US)

Correspondence Address: HUNTON & WILLIAMS LLP/VARIAN SEMICONDUCTOR,;EQUIPMENT ASSOCIATES, INC., INTELLECTUAL PROPERTY DEPARTMENT, 1900 K STREET, N.W., SUITE 1200, WASHINGTON, DC, 20006-1109, US

(73) Assignee: Varian Semiconductor Equipment Associates, Inc., Gloucester, MA (US)

(21) Appl. No.: 11/537,274

(22) Filed: Sep. 29, 2006

(51) Int. Cl. H01L 21/425; H01L 21/26; H01L 21/42

(52) U.S. Cl. 438/514; 438/513

(57) ABSTRACT

A technique for improved damage control in plasma doping (PLAD) ion implantation is disclosed. According to a particular exemplary embodiment, the technique may be realized as a method for improved damage control in plasma doping (PLAD) ion implantation. The method may comprise placing a wafer on a platen in a chamber. The method may also comprise generating a plasma in the chamber. The method may additionally comprise implanting at least a portion of ions produced from the plasma into the wafer, wherein the wafer is cooled to a temperature no higher than 0° C during ion implantation, and wherein a dose rate associated with the portion of ions is at least 1×10¹³ atoms/cm²/second.

### FIELD OF THE DISCLOSURE

The present disclosure relates generally to semiconductor manufacturing and, more particularly, to a technique for improved damage control in plasma doping (PLAD) ion implantation.

### BACKGROUND OF THE DISCLOSURE

Ion implantation is the standard technique for depositing chemical species into a substrate by direct bombardment of the substrate with energized ions. In semiconductor fabrication, ion implanters are used primarily for doping processes that alter the type and level of conductivity of target materials. A precise doping profile in an integrated circuit (IC) substrate and its thin-film structure is often crucial for proper IC performance. To achieve a desired doping profile, one or more ion species may be implanted in different doses and at different energy levels. A specification of the ion species, doses, and energies is referred to as an ion implantation recipe.

FIG. 1 depicts a conventional ion implantation system, particularly a radio frequency plasma doping (RF-PLAD) system 100. As is typical for most RF-PLAD systems, the system 100 is housed in a high-vacuum environment. The plasma doping system 100 includes a plasma chamber 102 and a conductive chamber top 104. The chamber top 104 includes a top section 116, a first section 106, and second section 108. The top section 116 has a gas entry 118 for a process gas to enter. Once the process gas enters the gas entry 118 of the top section 116, it passes through a baffle 126 before proceeding to rest of the chamber top 104 and the chamber 102. The first section 106 of the chamber top 104 extends generally in a horizontal direction. The second section 108 of the chamber top 104 extends from the first section 106 in generally a vertical direction. A planar coil antenna 112 having a plurality of turns wraps around the second section 108. A helical coil antenna 114 having a plurality of turns typically sits on the first section 106 and surrounds the second section 108. The first and second sections 106, 108 are typically formed of a dielectric material 110 for transferring RF power to a plasma inside the chamber 102.

An RF source 130, e.g., an RF power supply, may be electrically connected to at least one of the planar coil antenna 112 and the helical coil antenna by an impedance matching network 132 that maximizes power transferred from the RF source 130 to the RF antennas 112, 114. When the RF source 130 resonates RF currents in the RF antennas 112, 114, the RF antennas 112, 114 induce RF currents into the chamber 102 and chamber top 104 to excite and ionize process gas for generating a plasma in the chamber 102.

The geometry of the first and second sections 106, 108 of the chamber top 104 and the configuration of the RF antennas 112, 114 are chosen so that a uniform plasma is generated. In addition, electromagnetic coupling may be adjusted with a coil adjuster 134 to improve uniformity of generated plasma.

A platen 124 is positioned in the chamber 102 below the baffle 126, which functions as an anode. A target wafer 120 is positioned on a surface of the platen 124, which may be biased by a voltage power supply 128, so that ions in generated plasma are attracted to the target wafer 120.

Referring to FIG. 2, a typical ion implantation method 200 is shown. As is typical for RF-PLAD, the ion implantation method 200 includes placing a wafer in a chamber on a platen 210, generating a plasma in the chamber 220, pulsing the wafer with DC bias 230, implanting ions on the wafer 240, and removing the wafer from the chamber 250.

Placing a wafer in a chamber on a platen 210 may include securing, e.g., clamping, the wafer on the platen. Generating a plasma in the chamber 220 may include supplying gas in the chamber under predetermined process conditions and applying RF energy to create plasma in the chamber. Implanting ions on the wafer 240 generally corresponds to pulsing the wafer with DC bias 230. Thus, delivering 5 mA of current through a DC bias in non-PLAD, for example, assuming the scan speed and other implant parameters are set, may achieve an approximate dose rate of 2.5×10¹³ atoms/cm²/second during implantation and before the wafer is finally removed 250.

During an ion implantation process, a desired impurity material is typically ionized in an ion source, the resultant ions are accelerated to form an ion beam of prescribed energy, and the ion beam is then directed at a surface of a substrate, such as a silicon wafer. Constituent ions in the ion beam may be referred to as “beam ions” or “dopant ions.”

The beam ions typically penetrate into the target substrate and lose energy by interacting with electrons in the substrate (a mechanism known as “electronic stopping”) or by undergoing collisions with the substrate nuclei (a mechanism known as “nuclear stopping”). Electronic stopping can be analogized to a viscous drag on the ions, and does not lead to permanent damage to the substrate's crystal lattice. In contrast, nuclear stopping may lead to the displacement of a substrate atom, leaving a vacancy in the lattice. The displaced atom may become an interstitial, i.e., located at a site between lattice positions of atoms in the substrate's crystal structure. A vacancy-interstitial pair formed when an atom is displaced from a lattice site to an interstitial site is referred to as a “Frenkel pair.” One beam ion may undergo many nuclear collisions, and the resulting displaced atoms may themselves have enough energy to undergo their own nuclear collisions and create further displaced atoms, a phenomenon known as a “collision cascade.”

When the beam ions and all the displaced atoms have come to a rest, the crystal structure of the substrate will contain primary damages, consisting of vacancies and interstitials. The interstitials tend to be knocked deeper into the substrate by the beam ion collisions, and so the damage associated with the interstitials accumulates at ranges associated with the greatest depth (end-of-range or EOR) attained by the dopant ions. The extent of primary damages formed depends on various characteristics of the ion beam, such as beam energy, ion mass, total implanted dose, and implanted dose rate, and on characteristics of the substrate such as atomic composition, mass and crystal orientation with respect to the ion beam.

Once formed, interstitials and vacancies can diffuse through the substrate. If a vacancy and an interstitial interact, they may recombine, reverting to the original crystal lattice. Alternatively, a vacancy and an interstitial can recombine in such a way as to leave a defect in the lattice. If multiple vacancies, or interstitials, interact with each other, they may form other stable, secondary damage structures. If the damage in a region of the lattice reaches a critical density, the crystal converts into a metastable state, known as amorphous silicon. The diffusivity of the vacancies and interstitials, and therefore the rate of damage repair during ion implantation, are often enhanced as the substrate temperature increases. Substrate temperature is therefore an important parameter that may influence the amount and characteristics of damage remaining after an ion implantation process.

Low-temperature ion implantation has been investigated as a technique for achieving ultra-shallow junctions needed in modern complementary metal-oxide-semiconductor (CMOS) devices. Most low-temperature ion implantation approaches so far have focused on a simplistic goal of lowering wafer temperature as much as possible. There has not been any serious attempt to monitor or control other parameters during ion implantation, in addition to temperature, such as dose rate, which may also minimize the detrimental effects of end-of-range (EOR) defects, e.g., leakage current and transient enhanced diffusion resulting from amorphizing implants.

In view of the foregoing, it would be desirable to provide a technique for improved damage control to overcome the above-described inadequacies and shortcomings.

### SUMMARY OF THE DISCLOSURE

A technique for improved damage control in plasma doping (PLAD) ion implantation is disclosed. According to a particular exemplary embodiment, the technique may be realized as a method for improved damage control in plasma doping (PLAD) ion implantation. The method may comprise placing a wafer on a platen in a chamber. The method may also comprise generating a plasma in the chamber. The method may additionally comprise implanting at least a portion of ions produced from the plasma into the wafer, wherein the wafer is cooled to a temperature no higher than 0° C. during ion implantation.

In accordance with further aspects of this particular exemplary embodiment, a dose rate associated with the portion of ions is at least 1×10¹³ atoms/cm²/second.

In accordance with other aspects of this particular exemplary embodiment, the method reduces end-of-range defects, transient enhanced diffusion, and leakage current on the wafer.

In accordance with further aspects of this particular exemplary embodiment, the method is for RF-PLAD.

In accordance with additional aspects of this particular exemplary embodiment, the wafer is cooled to a temperature of approximately −20° C. to −40° C. during ion implantation.

In accordance with another aspect of this particular exemplary embodiment, the dose rate of the at least a portion of ions is approximately 5×10¹⁴ atoms/cm²/second.

The present disclosure will now be described in more detail with reference to exemplary embodiments thereof as shown in the accompanying drawings. While the present disclosure is described below with reference to exemplary embodiments, it should be understood that the present disclosure is not limited thereto. Those of ordinary skill in the art having access to the teachings herein will recognize additional implementations, modifications, and embodiments, as well as other fields of use, which are within the scope of the present disclosure as described herein, and with respect to which the present disclosure may be of significant utility.

### BRIEF DESCRIPTION OF THE DRAWINGS

In order to facilitate a fuller understanding of the present disclosure, reference is now made to the accompanying drawings, in which like elements are referenced with like numerals. These drawings should not be construed as limiting the present disclosure, but are intended to be exemplary only.

FIG. 1 depicts a conventional RF-PLAD ion implantation system.

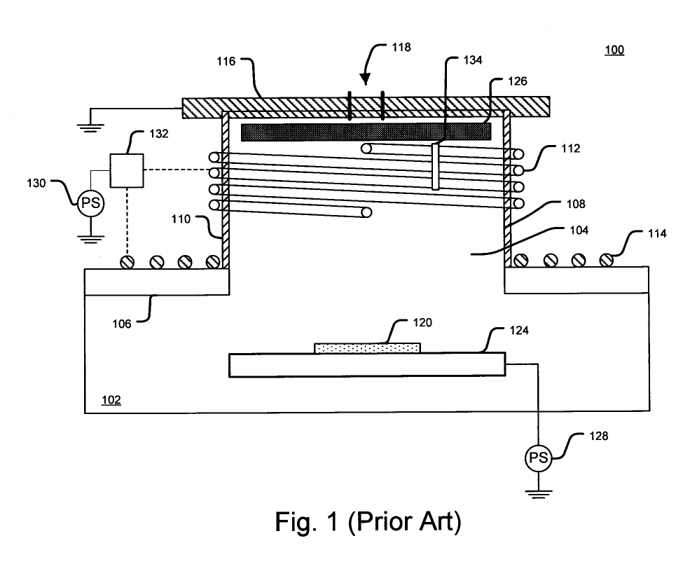

FIG. 2 depict a conventional RF-PLAD ion implantation method.

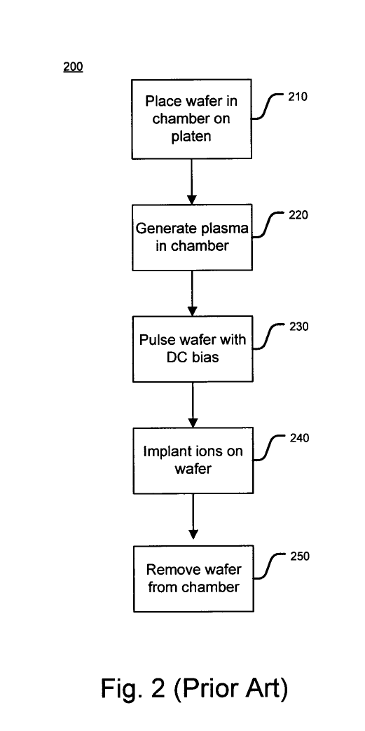

FIG. 3 depicts a flowchart illustrating an exemplary method for improved damage control in ion implantation according to an embodiment of the present disclosure.

FIG. 4 depicts a flowchart illustrating an exemplary method for improved damage control in ion implantation according to an embodiment of the present disclosure.

### DETAILED DESCRIPTION OF EXEMPLARY EMBODIMENTS

Embodiments of the present disclosure provide techniques for improved damage control in RF-PLAD ion implantation. In particular, the techniques may include reducing effects of end-of-range (EOR) defects. These EOR defects may be a source for injection of silicon self-interstitials that cause unwanted transient enhanced diffusion of an implanted dopant during annealing. Moreover, these defects may correspond to increased levels of leakage current measurements, which may be detrimental to semiconductor devices. Thus, techniques of the present disclosure may minimize EOR defects created by amorphizing implants. In addition, techniques of the present disclosure may improve activation efficiency of implanted dopants by controlling amorphous layer growth.

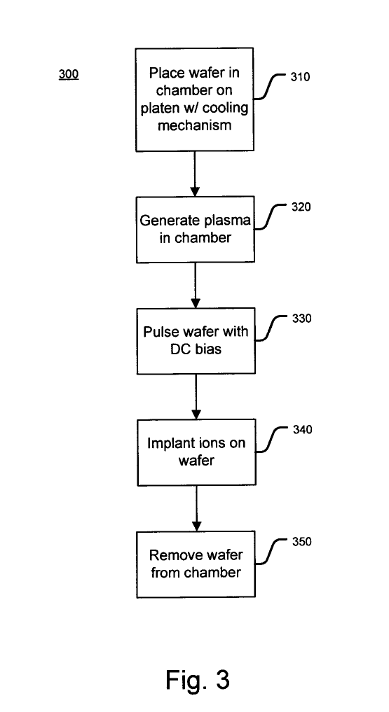

FIG. 3 depicts a flowchart illustrating an exemplary method 300 for improved damage control in ion implantation according to an embodiment of the present disclosure. The ion implantation method 300 may include placing a wafer in a chamber on a platen having a cooling mechanism 310, generating a plasma in the chamber 320, pulsing the wafer with DC bias 330 to control the dose rate when implanting ions on the wafer 340, and removing the wafer from the chamber 350.

In this embodiment, a wafer may begin to be cooled as soon as the wafer is placed on a platen in a chamber 310. A platen having a cooling mechanism may be used to control and decrease wafer temperature. A variety of cooling mechanisms may be utilized, such as gas cooling, coolant circulation, coolant phase change, Peltier heat transfer, built-in cryopumps, etc. Other cooling mechanisms may also be considered. The cooling process may continue in situ throughout the entire implantation process. Cooling may also be implemented intermittently during implantation. Other variations may also be considered.

Even though most typical cooling mechanisms have a capability to reduce a temperature of a wafer to approximately 4° C., the temperature in a typical method for ion implantation is generally slightly lower than room temperature, e.g., 20° C. However, decreasing the temperature of a wafer in a PLAD chamber to a temperature that is below freezing (0° C.) may substantially reduce the number EOR defects caused by transient enhanced diffusion. In one embodiment of the present disclosure, decreasing the temperature of a wafer to approximately −20° C. to −40° C. may be implemented.

Having relatively low wafer temperature during ion implantation may be advantageous for amorphization of a silicon wafer, which is desirable to create an ultra-shallow junction in a crystalline silicon wafer. Since amorphization of the silicon occurs only when a sufficient number of the silicon atoms are displaced by beam ions, the increase of Frenkel pair annihilation at high temperatures may work against the much needed amorphization process, resulting in a higher dose threshold for amorphization and therefore less than ideal shallow junctions.

With other parameters being the same, the thickness of an amorphous silicon layer may increase with decreasing implantation temperature due to a reduction of a self-annealing effect, e.g., the annihilation of Frenkel pairs (vacancy-interstitial pairs created from ion beam bombardments). With a thicker amorphous layer, less tail channeling may be expected. More damage created by beam ions may be confined in the amorphous region and less damage may be introduced into the crystalline region immediately beyond the amorphous-crystalline interface. Also, during a subsequent annealing, a better activation may be achieved as more dopants find themselves in substitutional sites due to a solid-phase epitaxy process.

In addition to the benefits introduced by a thicker amorphous silicon layer, performing ion implantation at low temperatures may also minimize the movement of Frenkel pairs during the implantation. Fewer Frenkel pairs may be pushed into the region beyond the amorphous-crystalline interface as compared to the case of higher temperature implantation. Most of the Frenkel pairs may grow back into the lattice during the solid-phase epitaxy process and may not contribute to excess interstitials which cause transient enhanced diffusion or form extended defects. Fewer excess interstitials may also lead to less impact of source-drain extension doping on channel or halo doping. With fewer interstitials pushing channel or halo dopants into a channel region, less negative coupling, such as reverse short channel effect, may be expected. Thus, better process control and prediction of device performance may be achieved.

Since rapid thermal anneals, such as diffusion-less anneals, are becoming a preferred post-implant process, in which a wafer may be heated to, for example, 1000° C. in 5 milliseconds, dopants have less time to diffuse significantly. There is also less time for the implant damage to be repaired. Thus, low-temperature ion implantation may improve the extent of implant damage repair during such anneals.

In addition to decreasing the temperature of a wafer, increasing a dose rate of an implant may also have significant effects. For example, by increasing a dose rate to approximately 5×10¹⁴ atoms/cm²/second during implantation, which is approximately 10 to 50 times that of typical dose rates, activation efficiency of implantation may be substantially improved. Increasing the pulse of DC bias to approximately 1×10¹¹ at 5 kHz, for example, may create a thicker amorphous layer to allow this enhanced activation effect and minimize EOR defects.

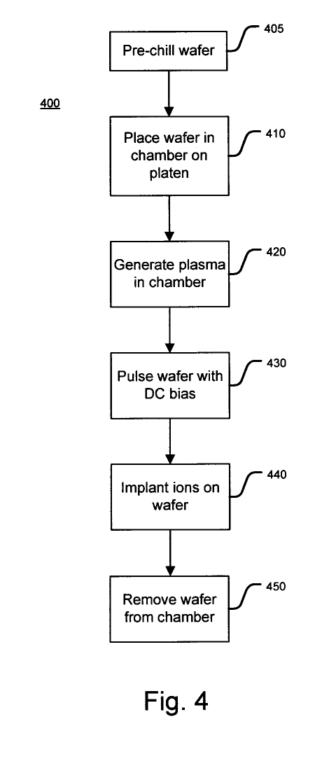

FIG. 4 depicts a flowchart illustrating another exemplary method for improved damage control in ion implantation according to an embodiment of the present disclosure. Instead of decreasing a temperature of a wafer by a cooling mechanism (i.e., as shown in FIG. 3), a wafer may be pre-chilled 405 before placing it in a chamber and on a platen.

In this embodiment, a wafer may be pre-chilled 405 to a desired temperature range so that during ion implantation, even as temperature increases, implantation proceeds at the desired low temperature, e.g., of approximately −20° C. to −40° C. Pre-chilling a wafer may be achieved by a pre-chill station, also known as a “thermal conditioning unit,” or other similar cooling mechanisms. Thus, in this embodiment, a wafer may not be actively or continuously cooled. In another embodiment, a wafer may be thermally insulated from a platen in order to reduce a temperature increase of the wafer.

According to an yet another embodiment of the present disclosure, a pre-chilled wafer may also be maintained or be further controlled by a cooling mechanism of a platen during ion implantation. A combination of pre-chilling a wafer before placing it on a platen and continuously chilling a wafer on a platen during implantation may achieve more controlled and consistent cooling to reduce unwanted defects.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Further, although the present disclosure has been described herein in the context of a particular implementation in a particular environment for a particular purpose, those of ordinary skill in the art will recognize that its usefulness is not limited thereto and that the present disclosure can be beneficially implemented in any number of environments for any number of purposes. Accordingly, the claims set forth below should be construed in view of the full breadth and spirit of the present disclosure as described herein.

1. A method for improved damage control in a plasma doping (PLAD) ion implantation process, the method comprising:
placing a wafer on a platen in a chamber;
generating a plasma in the chamber;
implanting at least a portion of ions produced from the plasma into the wafer, wherein the wafer is cooled to a temperature no higher than 0° C. during ion implantation.

2. The method of claim 1, wherein a dose rate associated with the portion of ions is at least 1×10¹³ atoms/cm²/second.

3. The method of claim 1, wherein the method reduces end-of-range defects, transient enhanced diffusion, and leakage current on the wafer.

4. The method of claim 2, wherein the method is for RF-PLAD.

5. The method of claim 1, wherein the wafer is cooled to a temperature of approximately −20° C. to −40° C. during ion implantation.

6. The method of claim 5, wherein cooling the wafer comprises pre-chilling the wafer before it is placed on the platen.

7. The method of claim 6, wherein the wafer is thermally insulated from the platen to minimize an increase in temperature.

8. The method of claim 5, wherein cooling the wafer comprises chilling the wafer with a cooling mechanism while the wafer is on a platen.

9. The method of claim 5, wherein cooling the wafer comprises pre-chilling the wafer before being placed on a platen and cooling the wafer with a cooling mechanism while the wafer is on a platen.

10. The method of claim 2, wherein increasing the dose rate of the at least a portion of ions comprises increasing the pulse rate of DC bias.

11. The method of claim 2, wherein the dose rate of the at least a portion of ions is increased approximately 10 to 50 fold.

12. The method of claim 11, wherein the dose rate of the at least a portion of ions is approximately 5×10¹⁴ atoms/cm²/second.

13. The method of claim 12, wherein the dose rate of the implant comprises a dose per pulse of approximately 1×10¹¹ at 5 kHz.
